(19) United States
(12) Patent Application Publication
(10) Pub. No.: US 2025/0200260 A1
(43) Pub. Date: Jun. 19, 2025

(54) MITIGATION OF CONTROL SET PACKING RESTRICTIONS FOR INTEGRATED CIRCUITS

(71) Applicant: Xilinx, Inc., San Jose, CA (US)

(72) Inventors: Sandip Maity, Hyderabad (IN); Aman Gayasen, Hyderabad (IN); Chun Zhang, San Jose, CA (US)

(73) Assignee: Xilinx, Inc., San Jose, CA (US)

(21) Appl. No.: 18/542,320

(22) Filed: Dec. 15, 2023

(51) Int. Cl. G06F 30/337

(52) U.S. Cl. CPC G06F 30/337

(57) ABSTRACT

Mitigation of controls set packing includes generating an Observability Don't Care (ODC) expression for a target register of a circuit design. The target register has an original reset signal that is a constant. A plurality of supports of the ODC expression that are driven by driver registers are grouped into a plurality of groups. Each group of the plurality of groups includes only supports that are driven by driver registers having a same reset signal. A control set of each group is different from a control set of the target register. The reset signal of a selected group of the plurality of groups is designated as a candidate reset signal for the target register based on an evaluation of the ODC expression. The circuit design is modified by connecting the candidate reset signal to the target register in place of the original reset signal.

### TECHNICAL FIELD

This disclosure relates to integrated circuits and, more particularly, to improving circuit design implementation in integrated circuits by mitigating control set packing restrictions.

### BACKGROUND

A control set refers to a unique collection of control signals including a clock signal, a clock enable signal, and a reset signal for registers of a circuit design. In complex circuit designs, reset signals, also referred to herein as “resets,” are an important consideration. Circuit components that have same control signals are said to be in, or belong to, the same control set.

Resets are a mechanism for forcing a circuit design, as physically realized in an integrated circuit (IC), into a known state in response to any of a variety of different conditions ranging from startup to encountering an unexpected error. Given that control sets are, at least in part, defined by resets, it follows that having a large number of different resets leads to a large number of control sets for a circuit design.

The implementation of a circuit design within an IC is subject to various constraints that arise from the circuit architecture of the IC. As an example, there are often constraints that limit the number of circuit components of different control sets that may be placed within certain circuit structures of the IC. These constraints may significantly impact the Quality of Result (QoR) of the circuit design as physically realized in the target IC.

For example, a circuit design with a given number of control sets may be implemented in an IC and use a particular number of circuit resources of that IC. A functionally equivalent version of the circuit design having fewer control sets may be implemented in the same IC in a more compact form that requires fewer circuit resources of the IC. Thus, the physical realization of the functionally equivalent circuit design with fewer control sets may require less area, consume less power, and/or have a higher operating frequency than the version of the circuit design with the larger number of control sets.

### SUMMARY

In an example, a method includes generating, by a processor, an Observability Don't Care (ODC) expression for a target register of a circuit design. The target register has an original reset signal that is a constant. The method includes grouping, by the processor, a plurality of supports of the ODC expression that are driven by driver registers into a plurality of groups. Each group of the plurality of groups includes only supports driven by driver registers having a same reset signal. A control set of each group is different from a control set of the target register. The method includes designating, by the processor, a reset signal of a selected group of the plurality of groups as a candidate reset signal for the target register based on an evaluation of the ODC expression. The method includes modifying, by the processor, the circuit design by connecting the candidate reset signal to the target register in place of the original reset signal. As noted, the original reset signal was constant.

The foregoing and other implementations can each optionally include one or more of the following features, alone or in combination. Some example implementations include all the following features in combination.

In some aspects, the evaluation includes replacing, within the ODC expression, a selected support of the selected group of the plurality of groups with a reset value of a driver register of the selected support. The evaluation includes evaluating the ODC expression to be a tautology subsequent to the replacing.

In some aspects, the driver register of the selected support of the selected group of the plurality of groups is compatible with the target register.

In some aspects, the designating designates the reset signal from each of two or more selected groups of the plurality of groups as the candidate reset signal resulting in a plurality of candidate reset signals. In that case, the method includes choosing a selected candidate reset signal from the plurality of candidate reset signals as the candidate reset signal connected to the target register in place of the original reset signal.

In some aspects, the selected candidate reset signal is chosen based on retiming compatibility of a resulting circuit architecture that includes the target register.

In some aspects, each group corresponding to a candidate reset signal corresponds to a respective control set of a plurality of control sets. The selected candidate reset signal corresponds to a largest control set of the plurality of control sets.

In some aspects, each candidate reset signal of the plurality of candidate reset signals corresponds to a respective control set of a plurality of control sets. The selected candidate reset signal is chosen post-placement of the circuit design for an integrated circuit based on available sites of the integrated circuit for the plurality of control sets corresponding to the plurality of candidate reset signals.

In an example, a system includes one or more hardware processors configured (e.g., programmed) to execute operations as described within this disclosure.

In one or more example implementations, a computer program product includes one or more computer readable storage mediums having program instructions embodied therewith. The program instructions are executable by computer hardware, e.g., a hardware processor, to cause the computer hardware to initiate and/or execute operations as described within this disclosure.

This Summary section is provided merely to introduce certain concepts and not to identify any key or essential features of the claimed subject matter. Other features of the inventive arrangements will be apparent from the accompanying drawings and from the following detailed description.

### BRIEF DESCRIPTION OF THE DRAWINGS

The inventive arrangements are illustrated by way of example in the accompanying drawings. The drawings, however, should not be construed to be limiting of the inventive arrangements to only the particular implementations shown. Various aspects and advantages will become apparent upon review of the following detailed description and upon reference to the drawings.

FIG. 1 illustrates certain operative features of an example system in accordance with the inventive arrangements described within this disclosure.

FIG. 2 illustrates an example method of processing a circuit design for implementation in an IC as performed by a system executing the framework of FIG. 1.

FIG. 3 illustrates an example of a circuit for which Observability Don't Care (ODC) expressions may be generated.

FIG. 4 illustrates an example of the processing performed by the candidate reset detector of FIG. 2.

FIG. 5 illustrates certain aspects of mitigation of control set packing restrictions with respect to implementation of a circuit design in an IC.

FIGS. 6A, 6B, and 6C illustrate certain aspects of mitigation of control set packing restrictions and the use of retiming.

FIG. 7 illustrates an example architecture for an IC.

FIG. 8 illustrates an example implementation of a data processing system.

### DETAILED DESCRIPTION

While the disclosure concludes with claims defining novel features, it is believed that the various features described within this disclosure will be better understood from a consideration of the description in conjunction with the drawings. The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to integrated circuits (ICs) and, more particularly, to improving circuit design implementation in ICs by mitigating control set packing restrictions. The inventive arrangements are capable of improving the Quality of Result (QoR) achieved for circuit designs as implemented in a given IC, referred to herein from time-to-time as a “target IC,” by providing multiple reset signal choices for registers within the circuit designs. A target IC refers to an IC having a particular circuit architecture such as a particular model and/or type of IC.

The term “control set” means two or more control pins of two or more different circuit components that are of a same control pin type, where the control pins of a same type are driven by same control signals. In this regard, examples of control pin types and corresponding control signals include a clock (CLK) pin (signal), a clock enable (CE) pin (signal), and a reset pin (signal). A reset signal, also referred to herein from time-to-time as a “reset,” may include a set signal, a reset signal, a clear signal, and a preset signal. A unique combination of CLK, CE, and reset signals forms a unique control set. Circuit components such as registers that have same control signals are said to be part of, included in, or members of, a same control set. That is, for example, two circuit components having same control pin types (e.g., CLK, CE, reset) each driven by same respective control signals are in a same control set.

An IC may have a circuit architecture that imposes certain limitations as to the number of different control sets that may be included within a given component of the IC. These limitations may vary from one model and/or type of IC to another. As an illustrative and non-limiting example, an IC such as a programmable IC may have an architecture that includes a plurality configurable logic blocks (CLBs). Each CLB includes one or more slice components. Each slice component, in turn, includes a fixed number of registers or register sites to which registers of a circuit design may be assigned (e.g., placed). The IC may have a restriction as to the number of registers of different control sets that may be assigned to a same slice component.

For purposes of discussion, consider an example in which a slice component of the IC is able to include only registers that belong to the same control set. In this example, one can see that having a large number of control sets in a circuit design may reduce the ability of the implementation tools to place the circuit design for the IC. Once the implementation tools place a register of the circuit design to a given slice component, other registers of the circuit design that belong to different control sets may not be placed in that same slice component. This can significantly limit the available sites to which registers may be placed. In consequence, the implementation tools may be forced to relocate registers to different slice components at different locations on the target IC to achieve a legal placement. This can lead to larger distances between components of the circuit design as placed, which requires more routing resources and leads to longer net delays (e.g., reduced QoR manifested as lower operating frequencies). Further, the implementation tools may be forced to leave certain register sites within the slice components of the IC empty, which wastes resources of the IC (e.g., reduced QoR as circuit designs require larger ICs for implementation).

The inventive arrangements provide methods, systems, and computer program products that are capable of detecting candidate resets for registers with no reset in circuit designs. A register with no reset is a register with a reset pin tied to a constant (e.g., to VDD or ground), where “constant” in this context means that the value of the signal does not change or is static. As defined within this disclosure, a candidate reset is a reset of a component of the circuit design that is different from an original reset of a register and that may be substituted for the original reset of the register without changing the functionality of the circuit design. The candidate resets are non-static signals. That is, the candidate resets are changing/dynamic signals that are not constant. Thus, a reset tied to VDD or ground would be excluded from consideration as a candidate reset. For a given register of a circuit design having one or more candidate resets, any one of the candidate resets may be used for the register in lieu of the original reset of the register without changing the functionality of the circuit design. That is, the functionality of the circuit design while using the original reset of the register is equivalent to the functionality of the circuit design after the original reset of the register is replaced with any one of the candidate resets.

By ascertaining one or more candidate resets for registers of a circuit design, the implementation tools are provided with greater flexibility during placement. A register with one or more candidate resets that may be used in lieu of the original reset of the register may be placed or assigned to a larger number of register sites on the target IC than had no candidate resets been detected for the register.

In some examples, “Observability Don't Care” (ODC)-based techniques are adapted to detect candidate resets for registers. With one or more candidate resets having been detected for each of one or more registers of a circuit design, the implementation tools are capable of processing the circuit design to optimize the placement of those registers as such registers will have a larger number of placement choices due to having multiple control set choices.

In one or more examples, optimization of control sets may include a reduction in the number of control sets of the circuit design and/or an increase in the number of members in one or more control sets (which may include a reduction in the number of members of other control sets). Having optimized the number of control sets in the circuit design by utilizing candidate resets for one or more registers of the circuit design, the resulting QoR of the circuit design as physically realized (e.g., implemented) in a target IC is improved. The improvement in QoR may manifest in one or more ways such as, for example, achieving a higher operating frequency for the resulting IC, obtaining shorter signal path delays as implemented in the target IC, and/or utilizing fewer resources of the target IC such that the target IC may implement a larger circuit design than otherwise would have been the case.

The inventive arrangements described within this disclosure may be used on circuit designs that are implemented in programmable ICs and on circuit designs that are implemented using Application-Specific ICs (ASICs). A programmable IC is an IC that includes at least some programmable circuitry. Programmable logic is an example of programmable circuitry. An example of a programmable IC is a Field Programmable Gate Array (FPGA). In the case of a programmable IC such as an FPGA, modifications to the circuit design based on replacement of register reset(s) with candidate reset(s) may be performed subject to particular heuristics that account for changes in the number and/or size of control sets of the circuit design. The heuristics may account for the underlying and fixed architecture of the FPGA. In one or more examples, the selection of a particular candidate reset to be used for a register over another candidate reset may be implemented based on such heuristics or other heuristics.

Further aspects of the inventive arrangements are described below with reference to the figures. For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

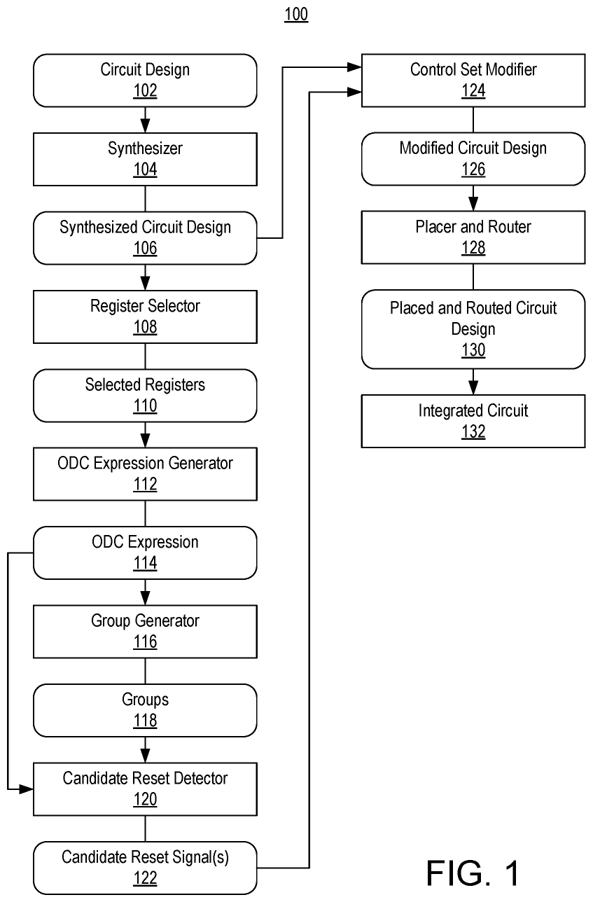

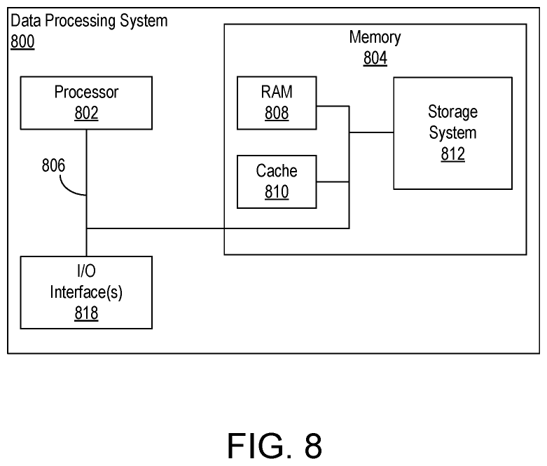

FIG. 1 illustrates certain operative features of an example system in accordance with the inventive arrangements described within this disclosure. FIG. 1 illustrates an example of a framework 100 that is executable by a data processing system, e.g., a computer, to perform the various operations described within this disclosure. A data processing system executing suitable operational software such as, for example, framework 100, is an example of an Electronic Design Automation (EDA) system. An example of a data processing system that may be used to execute framework 100 is described in connection with FIG. 8.

In the example, framework 100 includes a synthesizer 104, a register selector 108, an ODC expression generator 112, a group generator 116, a candidate reset detector 120, a control set modifier 124, and a placer and router 128. Framework 100 may include additional executable program code (not shown) for performing other operations described herein.

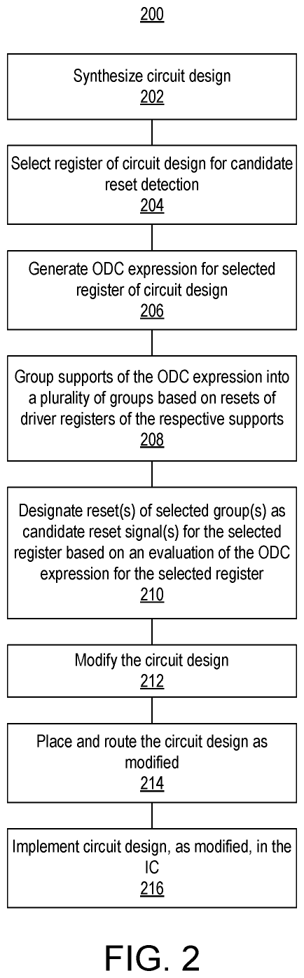

FIG. 2 illustrates an example method 200 of processing circuit design 102 for implementation in an IC 132 as performed by a system executing framework 100 of FIG. 1. Referring to FIGS. 1 and 2 collectively, in block 202, synthesizer 104 synthesizes circuit design 102 to generate synthesized circuit design 106. An example of a synthesized circuit design is a gate-level netlist.

Circuit design 102 may be specified as one or more register transfer level (RTL) description modules. Circuit design 102 may refer to an entire circuit design that includes user specified RTL; one or more cores and/or intellectual properties (IPs); a combination of user specified RTL, cores, and/or IP; a single IP and/or core (e.g., a reusable portion of RTL); or the like. The term “module” means a unit of RTL. A module may be defined within the syntax of the particular hardware description language (HDL) used to express the RTL description and may be part of a hierarchical organization of modules forming the circuit design.

In block 204, the system selects one or more registers of circuit design 102 for candidate reset detection. For example, synthesized circuit design 106 is provided to register selector 108. Register selector 108 searches synthesized circuit design 106 for one or more registers for which candidate resets will be detected. In one or more examples, register selector 108 searches synthesized circuit design 106 for registers that have a reset that is a constant. For example, register selector 108 searches synthesized circuit design 106 for registers that have a reset tied to a logic high (e.g., VDD) and/or for registers that have a reset tied to a logic low (e.g., ground). Such registers are selected by register selector 108 and are output as selected registers 110 (e.g., as a list of the one or more selected registers). Thus, selected registers 110 may include any register, or each register, of synthesized circuit design 106 that has a constant specified for the reset.

In block 206, the system generates ODC expressions 114 for the selected registers of circuit design 102. For example, synthesized circuit design 106 may be provided to ODC expression generator 112. ODC expression generator 112 is capable of generating ODC expressions 114 for selected registers 110. In one aspect, ODC expression generator 112 generates an ODC expression for each register of selected registers 110 of synthesized circuit design 106. As generally known, ODC expressions 114 are generated as Boolean conditions expressed in terms of signals of a circuit design. An ODC expression specifies the observability of any signal in a circuit design (e.g., RTL) as a Boolean expression under which the corresponding signal's value becomes observable or influences the value of one or more outputs of the circuit design. An ODC expression for a signal (e.g., as output from a circuit component) specifies the condition under which the signal's value has no impact on any of the circuit design's outputs.

Consider an example in which a circuit includes a register F that outputs a signal F used in some function to generate a network output of Z (e.g., signal Z) from the circuit. The network output Z is insensitive to the internal signal F when values of inputs to Z make the cofactors Z (F=0)==Z (F=1). The values may be found by solving the expression Z (F=0)⊕ Z (F=1)==1, which uses the exclusive NOR equality gate between the two cofactors. The expression also may be rewritten as [̅Z̅ (̅F̅=̅0̅)̅⊕̅Z̅ (̅F̅=̅1̅)̅]̅==1, which uses an exclusive OR between the two cofactors with the complement taken over the entire left portion of the expression. Based on these expressions, it can be said that when the expression dZ/dF evaluates to 1, the output Z is said to be sensitive to signal F. The ODC expression of register F is determined as the complement of dZ/dF written as

$${( \frac{dZ}{dF} )}^{′} .$$

When the Que expression of signal F,

$${( \frac{dZ}{dF} )}^{′} ,$$

evaluates to 1, the output Z is said to be insensitive to the signal F.

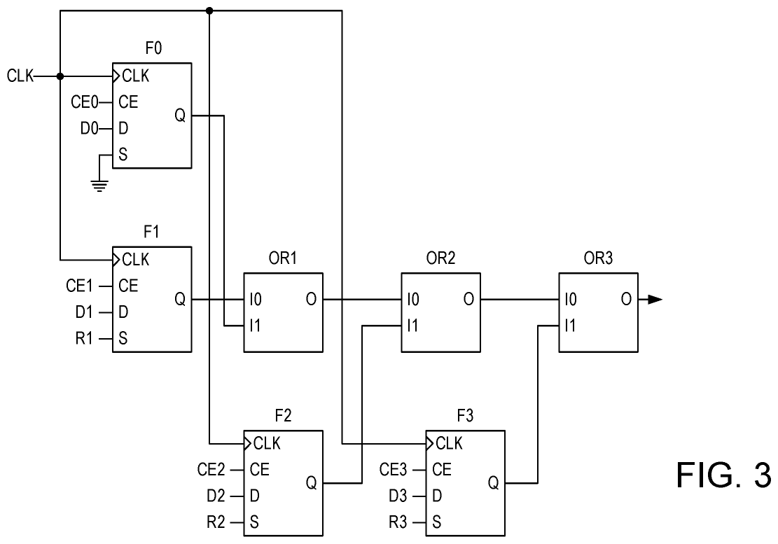

FIG. 3 illustrates an example circuit as may be specified by circuit design 102 and for which ODC expressions may be generated. In the example, the circuit design includes a plurality of different registers shown as F0, F1, F2, and F3. The example circuit also includes lookup tables (LUTs) illustrated as OR1 (e.g., a LUT implementing a logical OR function), OR2 (e.g., a LUT implementing a logical OR function), and OR3 (e.g., a LUT implementing another logical OR function).

In the example of FIG. 3, F0, F1, F2, and F3 are considered to be compatible. Compatibility is discussed in greater detail hereinbelow. In the example of FIG. 3, each register of F0, F1, F2, and F3 is driven by a same CLK signal and each register is of a same synchronization type (e.g., S). F0 has a constant as the reset signal. That is, the reset pin, e.g., the set or “S” pin in this example, is tied to ground. Each of the other registers F1, F2, and F3 has a different reset. For example, F1 has a reset of R1. F2 has a reset of R2. F3 has a reset of R3. Further, each reset of registers F1, F2, and F3 is different from the reset of register F0. In the example of FIG. 3, the ODC expression for F0 is F0=(F1+F2+F3). In the example ODC expression corresponding to FIG. 3, each of F0, F1, F2, and F3 represents the signal output from the respective register F0, F1, F2, and F3. Accordingly, in block 204, register selector 108 selects register F0 and in block 206, ODC expression generator 112 generates the ODC expression F0=(F1+F2+F3) for register F0.

The generation of ODC expressions for components of a circuit design such as registers is a practice that is well understood by those skilled in the art and that may be performed by any of a variety of available EDA-based circuit design implementation and/or analysis tools.

Within this disclosure, one or more of the operations of FIG. 2 are described, for purposes of illustration, as being performed in connection with a selected register (e.g., a single selected register). It should be appreciated that the embodiments described herein may be performed for a plurality of selected registers of a circuit design. For example, the operations described herein in connection with the selected register (e.g., 208 and 210) may be performed for a plurality of such registers or for each register of a plurality of such registers. Further, the “selected register” also may be referred to herein as the “target register.”

Accordingly, in block 208, for the selected or target register, the system groups supports specified by the ODC expression into a plurality of groups based on resets of the driver registers of the respective supports. In block 208, group generator 116 is capable of generating one or more groups 118. For example, group generator 116 is capable detecting each support included in the ODC expression for the selected register and creating group(s) 118 of the supports based on the resets of the respective driver registers of the supports. Those supports of the ODC expression driven by driver registers that have a same reset are placed in the same group. Thus, each support of the ODC expression for the selected register in a same group will necessarily be driven by a driver register having a same reset. The reset of the driver register of one group of supports will also be different from the reset of the driver register of another group of supports from the same ODC expression. Similarly, the reset of a driver register of a group generated for a selected register will have a reset that is different than the reset of the selected register.

Referring to the example of FIG. 3, the selected register is F0. The set of supports for the selected register is formed of supports F1, F2, and F3. From the ODC expression of the selected register of FIG. 3, group generator 116 collects each support of the ODC expression and the corresponding driver register. The support of the ODC expression is the signal.

Each group will be part of a different control set. Further, the control set of each group will be different from the control set of the selected register. In block 208, group generator 116, for purposes of generating groups, ignores or omits those supports that are not driven by a driver register. Such supports are omitted or excluded from inclusion in any group.

Given the ODC expression F0=(F1+F2+F3) for the selected register F0, the supports are F1, F2, and F3 in reference to the respective signals output from each of registers F1, F2, and F3. Thus, registers F1, F2, and F3 are the driver registers for the respective supports F1, F2, and F3. In this example, each register F1, F2, and F3 has a different reset than the selected register F0. In this example, because each support is driven by a driver register having a different or unique reset, group generator 116 generates three groups of supports with each group having a single support. Continuing with the example of FIG. 3, groups 118 include group 1 having support F1, group 2 having support F2, and group 3 having support F3.

In block 210, the system designates reset signal(s) of one or more selected group(s) 118 as candidate resets for the selected register. Reset signal(s) are designated as candidate resets based on an evaluation of the ODC expression of the selected register. Candidate reset detector 120 is capable of evaluating the ODC expression of the selected register and designating the reset signal of any group of groups 118 that meets predetermined criteria as a candidate reset for the selected register.

In an example, candidate reset detector 120 is capable of testing each group of the groups 118 to determine whether the reset of the group may be considered a candidate reset for the selected register. In general, candidate reset detector 120 determines whether the reset of a group may be connected to the reset pin (e.g., S pin in FIG. 3) of the selected register while preserving the functional equivalence of the circuit design.

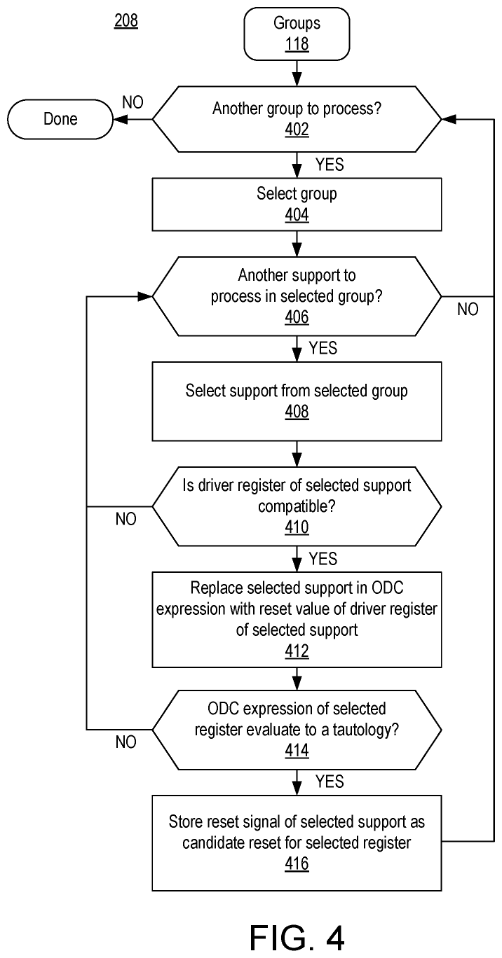

In one aspect, candidate reset detector 120 performs this test by substituting, within the ODC expression of the selected register, a selected support of a group having driver registers that are compatible with the selected register one-by-one with the reset value for the driver register of the selected support. Candidate reset detector 120 evaluates the ODC expression with the substituted value and checks whether the ODC expression evaluates to a tautology. In response to the ODC expression evaluating to a tautology, e.g., evaluating to “1,” candidate reset detector 120 selects the reset signal of the group as a candidate reset for the selected register. The reset signal may be stored as part of a set of candidate reset signal(s) 122 for the selected register. Operation of candidate reset detector 120 is described in greater detail in connection with FIG. 4.

Conventional approaches are unable to process mixed sync-type registers in ODC expressions. The “sync-type” of a register refers to whether the register is synchronous or asynchronous. Since conventional approaches check that the reset domain of registers is identical and allow only assertion of synchronous registers for synchronous target registers, conventional approaches may fail to identify the reset(s) of particular registers as a candidate reset for the selected register. The inventive arrangements described within this disclosure allow assertion of asynchronous register(s) for a synchronous target register, which may increase the number of candidate resets for the selected register.

In block 212, the system is capable of modifying the circuit design. That is, control set modifier 124 is capable of modifying synthesized circuit design 106 by connecting a candidate reset to the selected register. For example, control set modifier 124 disconnects the reset that is connected to the reset pin of the selected register (e.g., the original reset) and connects a selected candidate reset to the reset pin of the selected register resulting in a modified circuit design 126. Modified circuit design 126 is another version of circuit design 102 and/or synthesized circuit design 106. Modified circuit design 126 is functionally equivalent to circuit design 102 and/or synthesized circuit design 106 albeit having been optimized with respect to control sets for improved QoR.

The particular candidate reset that is connected to the selected register may be selected by control set modifier 124 based on one or more heuristics. That is, in the case where a plurality of candidate resets for the selected register are found, control set modifier 124 is capable of selecting the particular candidate reset to be used from the plurality of candidate resets based on one or more heuristics. In one or more examples, the heuristic(s) also may be used to determine whether the original reset for the selected register should continue to be used for the circuit design rather than any of the one or more candidate reset(s) that may have been found.

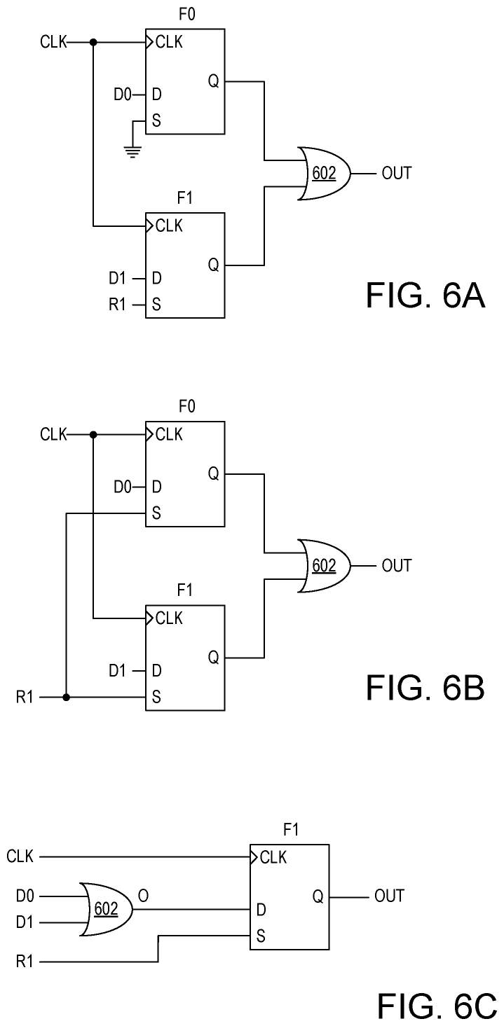

In an example, the particular candidate reset chosen from the plurality of candidate resets as the selected candidate reset is chosen based on retiming compatibility of the circuit architecture of a portion of the circuit design that includes the register. That is, control set modifier 124 determines whether, in replacing the original reset of the selected register with a particular candidate reset, the resulting circuit architecture of the portion of circuit design 102 that includes the selected register is compatible with a retiming operation. In response to determining that the resulting circuit architecture is compatible with a retiming operation (e.g., a forward retiming operation), the candidate reset is chosen as the selected candidate reset and used to replace the original reset of the selected register. An example of a circuit architecture that is compatible with a retiming operation is illustrated in FIG. 6B. An example retiming operation is illustrated in FIG. 6C.

In another example, each group (e.g., as generated in block 208) corresponding to a candidate reset corresponds to a respective control set of a plurality of control sets. Control set modifier 124 is capable of choosing the candidate reset as the selected candidate reset that corresponds to a largest control set of the plurality of control sets. That is, control set modifier 124 selects, from among the control sets corresponding to the candidate resets, the candidate reset that belongs to the control set with the largest number of member circuit components or that will have the largest number of member circuit components once the selected register is included. This operation can increase, by the largest degree, the number of available sites to which the selected component may be placed.

For example, prior to placement, control set modifier 124 is capable of considering the sizes of the control sets as a metric to select the candidate reset. Consider an example in which selected register F0 has three candidate resets R1, R2, and R3. The corresponding control sets of the candidate resets are CTRL_SET1={CLK, CE1, R1}, CTRL_SET2={CLK, CE2, R2} and CTRL_SET3={CLK, CE3, R3}. In this example, the reset of CTRL_SET1 is selected by control set modifier 124 if a size of CTRL_SET1 is or becomes greater than a size of the other two control sets. Selecting the candidate reset belonging to the largest control set as described provides the implementation tools (e.g., the placer) with the greatest amount of flexibility during placement and increases the likelihood of obtaining an improved QoR of the circuit design implementation.

In one or more examples, in cases where the number of members of each control set corresponding to a candidate reset is fewer (e.g., less than) the number of members of the control set of the selected register using the original reset, the system may choose to leave the selected register unchanged so that the original reset is maintained.

In another example, the modifying operation may be performed post-placement. For example, the modifying operation may be performed as part of a physical optimization phase. In that case, each candidate reset of the plurality of candidate resets corresponds to a respective control set of a plurality of control sets. The candidate reset chosen as the selected candidate reset is chosen post-placement of circuit design 102 based on available sites of IC 132 for the plurality of control sets corresponding to the plurality of candidate resets.

For example, control set modifier 124 may evaluate each of the slice component choices for each different candidate reset and select the candidate reset that provides the best QoR. If, for example, there are three reset candidates R1, R2, and R3 for selected register F0, where the corresponding control sets are CTRL_SET1={CLK, CE1, R1}, CTRL_SET2={CLK, CE2, R2} and CTRL_SET3={CLK, CE3, R3}, the placer will have a larger set of slice component choices for any one of the above control sets for packing register F0. That is, the available slices to which the selected register F0 may be placed are the slices for each of the control sets CTRL_SET1, CTRL_SET2, CTRL_SET3, and the original control set of the selected register. The larger number of available sites for the selected register mitigate the packing restrictions caused by the control set of the register with the original reset.

Referring to the above example where the available slices to which the selected register F0 may be placed are the slices for each of the control sets CTRL_SET1, CTRL_SET2, CTRL_SET3, and the original control set of the selected register, control set modifier 124 may choose the candidate reset as the selected candidate reset based on a distance heuristic. The distance heuristic, as determined by control set modifier 124, estimates any reduction in distance between the selected register and a load of the selected register that is achieved by replacing the original reset of the selected register with a candidate reset. The distance metric may be calculated for the selected register and each candidate reset. Control set modifier 124 may select the candidate reset that provides the greatest reduction in distance between the selected register and the load of the selected register based on available sites on the target IC for the respective control sets.

In one or more examples, control set modifier 124 may perform an initial filtering of the candidate resets to obtain those that provide a retiming opportunity (e.g., result in a circuit architecture upon which retiming such as forward retiming may be performed) and then apply one or more other heuristics to choose among the filtered candidate resets. For example, from among a plurality of candidate resets each providing an opportunity for retiming, control set modifier 124 may then choose the candidate reset that provides the best distance heuristic (e.g., smallest distance) and/or choose the candidate reset that results in a largest control set among the control sets of the candidate resets.

Having modified the circuit design as described, the resulting control set configuration will have an improved QoR. The circuit design, as modified, may be placed and routed resulting in a physical realization of the circuit design in the IC with an improved QoR. The resulting QoR of the circuit design as realized in an IC is improved (e.g., in terms of improved timing and improved IC resource utilization).

In block 214, the system is capable of placing and routing the circuit design as modified in block 212. As illustrated in FIG. 1, modified circuit design 126 may be provided to a placer and router 128 (e.g., collectively illustrated as block 128) to generate a placed and routed circuit design 130. Placed and routed circuit design 130 is placed and routed as modified by way of the control set optimization operations performed by control set modifier 124. As discussed, by using a different reset for a register (e.g., changing the control set to which the register belongs), the place and router 128 are provided with a larger number of options. The heuristic(s) used to select the candidate reset may be designed to facilitate improved placement and/or routing of the circuit design.

In some cases, the control set optimization(s) described, whether resulting in a reduced number of control sets or a same number of control sets with one or more of the control sets having an increased number of members, allows for a more efficient placement and/or routing of the circuit design thereby increasing the QoR of the circuit design as physically realized in the IC.

As discussed, in one or more examples, certain operations described in connection with FIGS. 1 and/or 2, e.g., block 212, may be performed post-placement.

In block 216, the system is capable of implementing placed and routed circuit design 130 in IC 132. That is, placed and routed circuit design 130 is physically realized within IC 132. Implementing placed and routed circuit design 130 may include manufacturing or fabricating IC 132 (e.g., where IC 132 is an ASIC) that implements placed and routed circuit design 130. In the case where IC 132 is a programmable IC such as an FPGA, implementing placed and routed circuit design 130 may include generating configuration data and loading that configuration data into IC 132, which physically realizes placed and routed circuit design 130 within IC 132.

Though not illustrated, it should be appreciated that any of a variety of different optimizations may be performed by the system on the circuit design at various stages of the design flow illustrated in FIGS. 1 and 2. In this regard, FIGS. 1 and 2 are not intended to be limitations on the particular design flow that may be implemented, but rather are provided as an example context in which the ODC-based control set optimization techniques described herein may be implemented.

FIG. 4 illustrates an example of the processing performed by candidate reset detector 120 as generally described in block 210 of FIG. 2. As illustrated, candidate reset detector 120 obtains groups 118 as generated by group generator 116. Referring to the example of FIG. 3, the groups 118 include group 1, group 2, and group 3. In block 402, candidate reset detector 120 determines whether there is another group left to process. In response to determining that no further groups remain to be processed, the method may end (e.g., block 210 may end so that processing in FIG. 2 continues to block 212). In response to determining that one or more groups remain to be processed, the method continues to block 404.

In block 404, candidate reset detector 120 selects a group from groups 118 to be processed. For purposes of illustration, candidate reset detector 120 selects group 1, which includes support F1.

In block 406, candidate reset detector 120 determines whether there is another support of the selected group left to process. In response to determining that no further supports of the selected group remain to be processed, the method loops back to block 402 to process a next group. In response to determining that one or more supports of the selected group remain to be processed, the method continues to block 408 where candidate reset detector 120 selects a support from the selected group. In this example, as group 1 includes only support F1, candidate reset detector 120 selects support F1.

In block 410, candidate reset detector 120 determines whether the driver register of the selected support is compatible with the selected or target register. More particularly, candidate reset detector 120 determines whether the driver of the selected support, i.e., register F1, is compatible with the selected register F0. The selected or target register is the register to which the ODC expression corresponds. Compatibility, as determined by candidate reset detector 120, is based on the clock signals and synchronization type of the driver register of the selected support and the selected register. To be considered compatible, registers must have compatibility with respect to clock signals and synchronization type. An incompatibility in any one of clock signals or synchronization type means the registers are not compatible (e.g., are incompatible).

With respect to clock signal compatibility, candidate reset detector 120 determines whether selected register F0 and register F1 are driven by a same clock signal. In this example, both selected register F0 and register F1 are driven by, e.g., have, the same clock signal. As illustrated in FIG. 3, the same CLK signal is distributed to the clock pin of selected register F0 and to the clock pin of register F1. Thus, the two registers are considered compatible with respect to the clock signals. If the two registers were clocked by different clock signals, the registers would be considered incompatible.

With respect to synchronization types, candidate reset detector 120 determines whether selected register F0 and register F1 have compatible synchronization types. In general, compatible synchronization types include the case where both registers have a same synchronization type. For example, if both selected register F0 and register F1 are synchronous, the two registers have a compatible synchronization type. If both selected register F0 and register F1 are asynchronous, the two registers have a compatible synchronization type. Compatible synchronization type also includes the case where the selected register F0 is synchronous and the register F1 is asynchronous. An incompatible synchronization type is where the selected register F0 is asynchronous and the register F1 is synchronous.

For purposes of illustration, each register of the example of FIG. 3 is a synchronous register and has a same clock signal. Thus, any combination the selected register F0 and a register (F1, F2, or F3) will be considered compatible.

In block 412, candidate reset detector 120 replaces the selected support in the ODC expression with the reset value of the selected support. As defined herein, the term “reset value” means the value output from a driver register of a selected support with the reset of the driver register asserted. For purposes of illustration, the reset value of a reset register is 0 since the reset register outputs a 0 when the reset of the reset register is asserted. Correspondingly, the reset value of a set register is 1 since the set register outputs a value of 1 when the reset of the set register is asserted. Appreciably, the type of driver register (e.g., set or reset) may be determined by the system from the circuit design as synthesized. Each support in the same group is driven by a driver register having a same reset. Each support in that group may or may not have a same reset value used to replace the respective support in the ODC expression. In cases where each register in the group is a set register or each register in the group is a reset register, each support in the group will have a same reset value. In cases where the group includes one or more reset registers and one or more set registers, each support in the group will not have a same reset value. For example, a set register and a reset register that have a same reset will have reset values of 1 and 0, respectively.

In illustration of the replacement process, within the ODC expression F0=(F1+F2+F3), the reset value of the register F1 is substituted in the expression for the support F1. The value output by F1 when the reset is asserted) is the “reset value” and is substituted for F1 in the ODC expression. As another example, consider the case where, in reference to the example of FIG. 3, register F1 has reset R1, but that registers F2 and F3 have reset R2. In this varied example, register F2 is a set register while register F3 is a reset register. In this case, there will be two groups (instead of 3 as before) where group 1 includes F1 and group 2 includes F2 and F3. In this example, the reset values of F2 and F3 will be different.

In block 414, candidate reset detector 120 evaluates the ODC expression with the value of the reset as substituted for the selected support and determines whether the ODC expression evaluates to a tautology (e.g., equates to a value of 1). In response to determining that the ODC expression evaluates to a tautology, the method continues to block 416 where the reset of the driver register of the selected support is added to a list as a candidate reset. After block 416, the selected group need not be processed any further regardless of whether any further supports remain to be processed. Accordingly, the method loops back to block 402 to select a next group to be processed. In response to determining that the ODC expression does not evaluate to a tautology, the method loops back to block 406 to select a next support from the selected group for processing. In this manner, the method may iterate through each support of the selected group if a tautology is not detected.

The method may continue to iterate as described. The method iterates on a per-group basis and, for each group, checking each support one-by-one by substituting the reset value of the driver register of the selected support within the ODC expression. As discussed, once a support from a group is found to result in a tautology, the reset signal of the group is considered a candidate reset for the selected register and the group need not be processed any further.

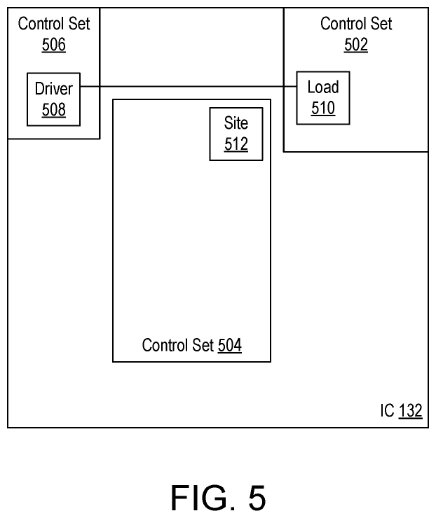

FIG. 5 illustrates an example implementation of circuit design 102 in IC 132. For purposes of illustration, circuit design 102, as implemented in IC 132, includes three control sets 502, 504, and 506. In the example, a net is shown having a driver 508 and a load 510. Driver 508 is part of control set 506. Load 510 is part of control set 502. For purposes of illustration, each control set is placed in a particular region of IC 132 with the circuit design 102 being implemented as originally processed through a design flow without utilizing the inventive arrangements.

In applying the inventive arrangements to the example of FIG. 5, a candidate reset is determined. More particularly, the system determines that the reset signal utilized by control set 504 may be used to replace the original reset of driver 508. By replacing the original reset of driver 508 with the reset of control set 504, driver 508 may be placed in the region of IC 132 defined by control set 504. For example, driver 508 may be placed at site 512. By placing driver 508 at site 512, which reduces the distance between driver 508 and load 510, circuit design 102 may achieve improved timing. FIG. 5 is provided as a simplified illustration of how the inventive arrangements provide a technical effect of an improved physical realization, e.g., in terms of improved QoR, of a circuit design in an IC.

As another illustrative example, if the reset of another control set were considered a candidate reset for driver 508, the distance metrics previously discussed may be used to select the particular candidate reset to be used for driver 508. That is, the distance between load 510 and site 512 may be compared to the distance between load 510 and an available site in the other control set may be compared with the system selecting the control set that minimizes the distance between driver 508 and load 510. Alternatively, the system may select the reset signal for the control set having the largest number of members between control set 504 and the other control set. As discussed, in one or more examples, in cases where the number of members of each control set corresponding to a candidate reset is fewer (e.g., less than) the number of members of the control set of the selected register using the original reset, the system may choose to leave the selected register unchanged so that the original reset is maintained.

FIGS. 6A, 6B, and 6C, taken collectively and collectively referred to as FIG. 6, illustrate how mitigation of control set packing restrictions provides retiming opportunities. In the example of FIG. 6A, registers F0 and F1 have a same clock signal and different reset signals. The system has detected register F0 as a selected register due to the reset pin of register F0 being tied to ground (e.g., the reset is a constant). For purposes of illustration, clock enable signals have been omitted. Further, reset R1 of register F1 has been detected by the system as a candidate reset for register F0.

FIG. 6B illustrates that the reset signal of register F0 has been changed to reset R1 of register F1 by application of the mitigation techniques described herein. In the examples of both FIGS. 6A and 6B, the output from each of registers F0 and F1 is connected to an input of OR gate 602. FIG. 6B is illustrative of a circuit architecture that is compatible with a retiming operation. In the example, a plurality of registers that receive same or different data but are members of a same control set provide outputs to a logic gate.

FIG. 6C illustrates application of a retiming technique by the system to the circuitry illustrated in FIG. 6B. More particularly, FIG. 6C illustrates an example of forward retiming. In the example, with both of registers F0 and F1 being part of a same control set, OR gate 602 may be relocated prior to registers F0 and F1. The input signals previously provided to the inputs of registers F0 and F1 (e.g., D0 and D1, respectively) are connected to the inputs of OR gate 602. The output of OR gate 602 is connected to register F1 (or alternatively F0). The other register, register F0 in this example, is removed from the circuit thereby reducing the amount of circuit component resources of the target IC that are needed to implement the circuit design. The signal OUT in each of FIGS. 6A, 6B, and 6C is/are functionally equivalent. FIG. 6 illustrates how implementation of the mitigation of control set packing restrictions as described herein places the resulting circuitry in a configuration or architecture in which retiming can be provided. Were the mitigation of control set packing restrictions not applied, retiming would not have been performed as registers F0 and F1 would remain in different control sets.

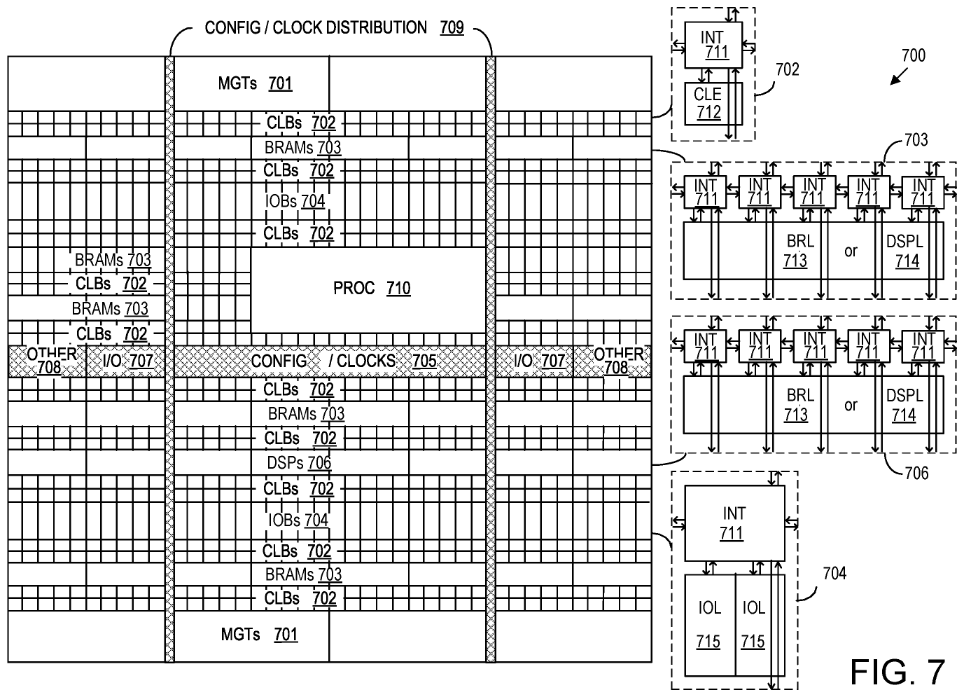

FIG. 7 illustrates an example architecture 700 for an IC. In one aspect, architecture 700 may be implemented within a programmable IC. For example, architecture 700 may be used to implement an FPGA. Architecture 700 may also be representative of a System-on-Chip (SoC) type of IC. An SoC refers to an IC that includes a plurality of different subsystems. An example of an SoC may include a computer implemented on a chip where the chip include a processor configured to execute program code, memory, and optionally one or more peripheral circuits. Another example of an SoC includes a chip having a processor configured to execute program code and one or more other circuits and/or subsystems. The other circuits may be implemented as hardwired circuitry, programmable circuitry, and/or a combination thereof. The circuits may operate cooperatively with one another and/or with the processor.

As shown, architecture 700 includes several different types of programmable circuit, e.g., logic, blocks. For example, architecture 700 may include a large number of different programmable tiles including multi-gigabit transceivers (MGTs) 701, configurable logic blocks (CLBs) 702, random access memory blocks (BRAMs) 703, input/output blocks (IOBs) 704, configuration and clocking logic (CONFIG/CLOCKS) 705, digital signal processing blocks (DSPs) 706, specialized I/O blocks 707 (e.g., configuration ports and clock ports), and other programmable logic 708 such as digital clock managers, analog-to-digital converters, system monitoring logic, and so forth.

In some ICs, each programmable tile includes a programmable interconnect element (INT) 711 having standardized connections to and from a corresponding INT 711 in each adjacent tile. Therefore, INTs 711, taken together, implement the programmable interconnect structure for the illustrated architecture 700. Each INT 711 also includes the connections to and from the programmable logic element within the same tile, as shown by the examples included at the top of FIG. 7.

For example, a CLB 702 may include a configurable logic element (CLE) 712 that may be programmed to implement user logic plus a single INT 711. A BRAM 703 may include a BRAM logic element (BRL) 713 in addition to one or more INTs 711. Typically, the number of INTs 711 included in a tile depends on the height of the tile. As pictured, a BRAM tile has the same height as five CLBs, but other numbers (e.g., four) also may be used. A DSP tile 706 may include a DSP logic element (DSPL) 714 in addition to an appropriate number of INTs 711. An IOB 704 may include, for example, two instances of an I/O logic element (IOL) 715 in addition to one instance of an INT 711. The actual I/O pads connected to IOL 715 may not be confined to the area of IOL 715.

In the example pictured in FIG. 7, a columnar area near the center of the die, e.g., formed of regions 705, 707, and 708, may be used for configuration, clock, and other control logic. Areas 709 extending from this column may be used to distribute the clocks and configuration signals across the breadth of the architecture 700.

Some ICs utilizing the architecture illustrated in FIG. 7 include additional logic blocks that disrupt the regular columnar structure making up a large part of the IC. The additional logic blocks may be programmable blocks and/or dedicated circuitry. For example, a processor block depicted as PROC 710 spans several columns of CLBs and BRAMs.

In one aspect, PROC 710 may be implemented as dedicated circuitry, e.g., as a hardwired processor, that is fabricated as part of the die that implements the programmable circuitry of the IC. PROC 710 may represent any of a variety of different processor types and/or systems ranging in complexity from an individual processor, e.g., a single core capable of executing program code, to an entire processor system having one or more cores, modules, co-processors, interfaces, or the like. In one or more other examples, PROC 710 may represent a data processing array including a plurality of processors arranged in a grid.

In another aspect, PROC 710 may be omitted from architecture 700 and replaced with one or more of the other varieties of the programmable blocks described. Further, such blocks may be utilized to form a “soft processor” in that the various blocks of programmable circuitry may be used to form a processor that can execute program code as is the case with PROC 710.

The phrase “programmable circuitry” means circuitry used to rebuild reconfigurable digital circuits. With reference to FIG. 7, the programmable circuitry refers to the programmable circuit elements (e.g., the programmable or configurable circuit blocks or tiles described herein and the interconnect circuitry that selectively couples the various circuit blocks, tiles, and/or elements according to configuration data that is loaded into the IC). For example, circuit blocks shown in FIG. 7 that are external to PROC 710 such as CLBs 702 and BRAMs 703 are considered programmable circuitry of the IC.

In general, the functionality of programmable circuitry is not established until configuration data is loaded into the IC. A set of configuration bits may be used to program programmable circuitry of an IC such as an FPGA. The configuration bit(s) typically are referred to as a “configuration bitstream” or “configuration data.” In one or more examples, placed and routed circuit design 130 is specified or implemented as configuration bits. In general, programmable circuitry is not operational or functional without first loading a configuration bitstream into the IC. The configuration bitstream effectively implements a particular circuit design within the programmable circuitry. The circuit design specifies, for example, functional aspects of the programmable circuit blocks and physical connectivity among the various programmable circuit blocks.

Circuitry that is “hardwired” or “hardened,” i.e., not programmable, is manufactured as part of the IC. Unlike programmable circuitry, hardwired circuitry or circuit blocks are not implemented after the manufacture of the IC through the loading of a configuration bitstream. Hardwired circuitry is generally considered to have dedicated circuit blocks and interconnects, for example, that are functional without first loading a configuration bitstream into the IC, e.g., PROC 710.

In some instances, hardwired circuitry may have one or more operational modes that can be set or selected according to register settings or values stored in one or more memory elements within the IC. The operational modes may be set, for example, through the loading of a configuration bitstream into the IC. Despite this ability, hardwired circuitry is not considered programmable circuitry as the hardwired circuitry is operable and has a particular function when manufactured as part of the IC.

In the case of an SoC, the configuration bitstream may specify the circuitry that is to be implemented within the programmable circuitry and the program code that is to be executed by PROC 710 or a soft processor. In some cases, architecture 700 includes a dedicated configuration processor that loads the configuration bitstream to the appropriate configuration memory and/or processor memory. The dedicated configuration processor does not execute user-specified program code. In other cases, architecture 700 may utilize PROC 710 to receive the configuration bitstream, load the configuration bitstream into appropriate configuration memory, and/or extract program code for execution.

FIG. 7 is intended to illustrate an example architecture that may be used to implement an IC that includes programmable circuitry, e.g., a programmable fabric. For example, the number of logic blocks in a column, the relative width of the columns, the number and order of columns, the types of logic blocks included in the columns, the relative sizes of the logic blocks, and the interconnect/logic implementations included at the top of FIG. 7 are purely illustrative. In an actual IC, for example, more than one adjacent column of CLBs is typically included wherever the CLBs appear, to facilitate the efficient implementation of a user circuit design. The number of adjacent CLB columns, however, may vary with the overall size of the IC. Further, the size and/or positioning of blocks such as PROC 710 within the IC are for purposes of illustration only and are not intended as limitations. Architecture 700 may be adapted such that the programmable circuitry/logic is a portion of a larger IC with one or more other subsystems included therein.

FIG. 8 illustrates an example implementation of a data processing system 800. As defined herein, the term “data processing system” means one or more hardware systems configured to process data, each hardware system including at least one processor and memory, wherein the processor is programmed with computer-readable instructions that, upon execution, perform or execute operations. Data processing system 800 can include a processor 802, a memory 804, and a bus 806 that couples various system components including memory 804 to processor 802.

Processor 802 may be implemented as one or more processors. In an example, processor 802 is implemented as a central processing unit (CPU). Processor 802 may be implemented as one or more circuits, e.g., hardware, capable of carrying out instructions contained in program code. The circuit may be an integrated circuit or embedded in an integrated circuit. Processor 802 may be implemented using a complex instruction set computer architecture (CISC), a reduced instruction set computer architecture (RISC), a vector processing architecture, or other known architecture. Example processors include, but are not limited to, processors having an x86 type of architecture (IA-32, IA-64, etc.), Power Architecture, ARM processors, and the like.

Bus 806 represents one or more of any of a variety of communication bus structures. By way of example, and not limitation, bus 806 may be implemented as a Peripheral Component Interconnect Express (PCIe) bus. Data processing system 800 typically includes a variety of computer system readable media. Such media may include computer-readable volatile and non-volatile media and computer-readable removable and non-removable media.

Memory 804 can include computer-readable media in the form of volatile memory, such as random-access memory (RAM) 808 and/or cache memory 810. Data processing system 800 also can include other removable/non-removable, volatile/non-volatile computer storage media. By way of example, storage system 812 can be provided for reading from and writing to a non-removable, non-volatile magnetic and/or solid-state media (not shown and typically called a “hard drive”), which may be included in storage system 812. Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 806 by one or more data media interfaces. Memory 804 is an example of at least one computer program product.

Memory 804 is capable of storing computer-readable program instructions that are executable by processor 802. For example, the computer-readable program instructions can include an operating system, one or more application programs, other program code, and program data. The computer-readable program code, upon execution, causes data processing system 800 (e.g., processor 802) to perform the operations described herein.

It should be appreciated that data items used, generated, and/or operated upon by data processing system 800 are functional data structures that impart functionality when employed by data processing system 800. As defined within this disclosure, the term “data structure” means a physical implementation of a data model's organization of data within a physical memory. As such, a data structure is formed of specific electrical or magnetic structural elements in a memory. A data structure imposes physical organization on the data stored in the memory as used by an application program executed using a processor.

Data processing system 800 may include one or more Input/Output (I/O) interfaces 818 coupled to bus 806. I/O interface(s) 818 allow data processing system 800 to communicate with one or more external devices and/or communicate over one or more networks such as a local area network (LAN), a wide area network (WAN), and/or a public network (e.g., the Internet). Examples of I/O interfaces 818 may include, but are not limited to, network cards, modems, network adapters, hardware controllers, etc. Examples of external devices also may include devices that allow a user to interact with data processing system 800 (e.g., a display, a keyboard, and/or a pointing device) and/or other devices such as accelerator card.

Data processing system 800 is only one example implementation. Data processing system 800 can be practiced as a standalone device (e.g., as a user computing device or a server, as a bare metal server), in a cluster (e.g., two or more interconnected computers), or in a distributed cloud computing environment (e.g., as a cloud computing node) where tasks are performed by remote processing devices that are linked through a communications network. In a distributed cloud computing environment, program modules may be located in both local and remote computer system storage media including memory storage devices.

The example of FIG. 8 is not intended to suggest any limitation as to the scope of use or functionality of example implementations described herein. Data processing system 800 is an example of computer hardware that is capable of performing the various operations described within this disclosure. Data processing system 800 may include fewer components than shown or additional components not illustrated in FIG. 8 depending upon the particular type of device and/or system that is implemented. The particular operating system and/or application(s) included may vary according to device and/or system type as may the types of I/O devices included. Further, one or more of the illustrative components may be incorporated into, or otherwise form a portion of, another component. For example, a processor may include at least some memory.

The terminology used herein is for the purpose of describing particular embodiments only and is not intended to be limiting. Notwithstanding, several definitions that apply throughout this document are expressly defined as follows.

As defined herein, the singular forms “a,” “an,” and “the” are intended to include the plural forms as well, unless the context clearly indicates otherwise.

As defined herein, the term “automatically” means without human intervention.

As defined herein, the term “computer-readable storage medium” means a storage medium that contains or stores program instructions for use by or in connection with an instruction execution system, apparatus, or device. As defined herein, a “computer-readable storage medium” is not a transitory, propagating signal per se. The various forms of memory, as described herein, are examples of computer-readable storage media. A non-exhaustive list of examples of computer-readable storage media include an electronic storage device, a magnetic storage device, an optical storage device, an electromagnetic storage device, a semiconductor storage device, or any suitable combination of the foregoing. A non-exhaustive list of more specific examples of a computer-readable storage medium may include: a portable computer diskette, a hard disk, a RAM, a read-only memory (ROM), an erasable programmable read-only memory (EPROM or Flash memory), an electronically erasable programmable read-only memory (EEPROM), a static random-access memory (SRAM), a portable compact disc read-only memory (CD-ROM), a digital versatile disk (DVD), a memory stick, a floppy disk, or the like.

As defined herein, the term “responsive to” and similar language as described above, e.g., “if,” “when,” or “upon,” means responding or reacting readily to an action or event. The response or reaction is performed automatically. Thus, if a second action is performed “responsive to” a first action, there is a causal relationship between an occurrence of the first action and an occurrence of the second action. The term “responsive to” indicates the causal relationship.

As defined herein, the terms “individual” and “user” each refer to a human being.

As defined herein, the term “hardware processor” means at least one hardware circuit. The hardware circuit is configured to carry out instructions contained in program code. The hardware circuit may be an integrated circuit. Examples of a hardware processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, and a controller.

As defined herein, the terms “one embodiment,” “an embodiment,” “in one or more embodiments,” “in particular embodiments,” or similar language mean that a particular feature, structure, or characteristic described in connection with the embodiment is included in at least one embodiment described within this disclosure. Thus, appearances of the aforementioned phrases and/or similar language throughout this disclosure may, but do not necessarily, all refer to the same embodiment.

The terms first, second, etc. may be used herein to describe various elements. These elements should not be limited by these terms, as these terms are only used to distinguish one element from another unless stated otherwise or the context clearly indicates otherwise.

A computer program product may include a computer-readable storage medium (or media) having computer-readable program instructions thereon for causing a processor to carry out aspects of the inventive arrangements described herein. Within this disclosure, the terms “program code” is used interchangeably with the term “program instructions.” Computer-readable program instructions described herein may be downloaded to respective computing/processing devices from a computer-readable storage medium or to an external computer or external storage device via a network, for example, the Internet, a LAN, a WAN and/or a wireless network. The network may include copper transmission cables, optical transmission fibers, wireless transmission, routers, firewalls, switches, gateway computers and/or edge devices including edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations for the inventive arrangements described herein may be assembler instructions, instruction-set-architecture (ISA) instructions, machine instructions, machine dependent instructions, microcode, firmware instructions, or either source code or object code written in any combination of one or more programming languages, including an object-oriented programming language and/or procedural programming languages. Computer-readable program instructions may include state-setting data. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry including, for example, programmable logic circuitry, an FPGA, or a PLA may execute the computer-readable program instructions by utilizing state information of the computer-readable program instructions to personalize the electronic circuitry, in order to perform aspects of the inventive arrangements described herein.

Certain aspects of the inventive arrangements are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by computer-readable program instructions, e.g., program code.

These computer-readable program instructions may be provided to a processor of a computer, special-purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the operations specified in the flowchart and/or block diagram block or blocks.

The computer-readable program instructions may also be loaded onto a computer, other programmable data processing apparatus, or other device to cause a series of operations to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the inventive arrangements. In this regard, each block in the flowchart or block diagrams may represent a module, segment, or portion of instructions, which comprises one or more executable instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method, comprising:
generating, by a processor, an Observability Don't Care (ODC) expression for a target register of a circuit design, wherein the target register has an original reset signal that is a constant;
grouping, by the processor, a plurality of supports of the ODC expression that are driven by driver registers into a plurality of groups, wherein each group of the plurality of groups includes only supports driven by driver registers having a same reset signal, and wherein a control set of each group is different from a control set of the target register;
designating, by the processor, a reset signal of a selected group of the plurality of groups as a candidate reset signal for the target register based on an evaluation of the ODC expression; and
modifying, by the processor, the circuit design by connecting the candidate reset signal to the target register in place of the original reset signal.

2. The method of claim 1, wherein the evaluation includes:
replacing, within the ODC expression, a selected support of the selected group of the plurality of groups with a reset value of a driver register of the selected support; and
evaluating the ODC expression to be a tautology subsequent to the replacing.

3. The method of claim 2, wherein the driver register of the selected support of the selected group of the plurality of groups is compatible with the target register.

4. The method of claim 1, wherein the designating designates the reset signal from each of two or more selected groups of the plurality of groups as the candidate reset signal resulting in a plurality of candidate reset signals, the method further comprising:
choosing a selected candidate reset signal from the plurality of candidate reset signals as the candidate reset signal connected to the target register in place of the original reset signal.

5. The method of claim 4, wherein the selected candidate reset signal is chosen based on retiming compatibility of a resulting circuit architecture that includes the target register.

6. The method of claim 4, wherein each group corresponding to a candidate reset signal corresponds to a respective control set of a plurality of control sets, and wherein the selected candidate reset signal corresponds to a largest control set of the plurality of control sets.

7. The method of claim 4, wherein each candidate reset signal of the plurality of candidate reset signals corresponds to a respective control set of a plurality of control sets, wherein the selected candidate reset signal is chosen post-placement of the circuit design for an integrated circuit based on available sites of the integrated circuit for the plurality of control sets corresponding to the plurality of candidate reset signals.

8. A system, comprising:
one or more hardware processors configured to initiate operations including:
generating an Observability Don't Care (ODC) expression for a target register of a circuit design, wherein the target register has an original reset signal that is a constant;
grouping a plurality of supports of the ODC expression that are driven by driver registers into a plurality of groups, wherein each group of the plurality of groups includes only supports driven by driver registers having a same reset signal, and wherein a control set of each group is different from a control set of the target register;
designating a reset signal of a selected group of the plurality of groups as a candidate reset signal for the target register based on an evaluation of the ODC expression; and
modifying the circuit design by connecting the candidate reset signal to the target register in place of the original reset signal.

9. The system of claim 8, wherein the evaluation includes:
replacing, within the ODC expression, a selected support of the selected group of the plurality of groups with a reset value of a driver register of the selected support; and
evaluating the ODC expression to be a tautology subsequent to the replacing.

10. The system of claim 9, wherein the driver register of the selected support of the selected group of the plurality of groups is compatible with the target register.

11. The system of claim 8, wherein the designating designates the reset signal from each of two or more selected groups of the plurality of groups as the candidate reset signal resulting in a plurality of candidate reset signals, wherein the one or more hardware processors are configured to initiate operations further comprising:
choosing a selected candidate reset signal from the plurality of candidate reset signals as the candidate reset signal connected to the target register in place of the original reset signal.

12. The system of claim 11, wherein the selected candidate reset signal is chosen based on retiming compatibility of a resulting circuit architecture that includes the target register.

13. The system of claim 11, wherein each group corresponding to a candidate reset signal corresponds to a respective control set of a plurality of control sets, and wherein the selected candidate reset signal corresponds to a largest control set of the plurality of control sets.

14. The system of claim 11, wherein each candidate reset signal of the plurality of candidate reset signals corresponds to a respective control set of a plurality of control sets, wherein the selected candidate reset signal is chosen post-placement of the circuit design for an integrated circuit based on available sites of the integrated circuit for the plurality of control sets corresponding to the plurality of candidate reset signals.

15. A computer program product comprising one or more computer readable storage mediums having program instructions embodied therewith, wherein the program instructions are executable by computer hardware to cause the computer hardware to execute operations comprising:
generating an Observability Don't Care (ODC) expression for a target register of a circuit design, wherein the target register has an original reset signal that is a constant;
grouping a plurality of supports of the ODC expression that are driven by driver registers into a plurality of groups, wherein each group of the plurality of groups includes only supports driven by driver registers having a same reset signal, and wherein a control set of each group is different from a control set of the target register;
designating a reset signal of a selected group of the plurality of groups as a candidate reset signal for the target register based on an evaluation of the ODC expression; and
modifying the circuit design by connecting the candidate reset signal to the target register in place of the original reset signal.

16. The computer program product of claim 15, wherein the evaluation includes:
replacing, within the ODC expression, a selected support of the selected group of the plurality of groups with a reset value of a driver register of the selected support; and
evaluating the ODC expression to be a tautology subsequent to the replacing.

17. The computer program product of claim 16, wherein the driver register of the selected support of the selected group of the plurality of groups is compatible with the target register.

18. The computer program product of claim 15, wherein the designating designates the reset signal from each of two or more selected groups of the plurality of groups as the candidate reset signal resulting in a plurality of candidate reset signals, wherein the program instructions are executable by computer hardware to cause the computer hardware to execute operations comprising:
choosing a selected candidate reset signal from the plurality of candidate reset signals as the candidate reset signal connected to the target register in place of the original reset signal.

19. The computer program product of claim 18, wherein:
the selected candidate reset signal is chosen based on retiming compatibility of a resulting circuit architecture that includes the target register; or
wherein each group corresponding to a candidate reset signal corresponds to a respective control set of a plurality of control sets, and wherein the selected candidate reset signal corresponds to a largest control set of the plurality of control sets.

20. The computer program product of claim 18, wherein each candidate reset signal of the plurality of candidate reset signals corresponds to a respective control set of a plurality of control sets, wherein the selected candidate reset signal is chosen post-placement of the circuit design for an integrated circuit based on available sites of the integrated circuit for the plurality of control sets corresponding to the plurality of candidate reset signals.
